(19) United States
(12) Patent Application Publication
(10) Pub. No.: US 2025/0138426 A1
(43) Pub. Date: May 1, 2025

(54) SILICON-CONTAINING MOLECULAR GLASS PHOTORESIST COMPOUND WITH HIGH ETCHING RESISTANCE, PREPARATION METHOD THEREFOR, AND USE THEREOF

(71) Applicant: INSTITUTE OF CHEMISTRY, CHINESE ACADEMY OF SCIENCES, Beijing (CN)

(72) Inventors: Guoqiang YANG, Beijing (CN); Siliang ZHANG, Beijing (CN); Xudong GUO, Beijing (CN); Rui HU, Beijing (CN); Shuangqing WANG, Beijing (CN)

(21) Appl. No.: 18/692,248

(22) PCT Filed: Oct. 28, 2022
(86) PCT No.: PCT/CN2022/128209

§ 371 Date: Mar. 14, 2024

(51) Int. Cl. G03F 7/075

(52) U.S. Cl. CPC G03F 7/0755

(57) ABSTRACT

A silicon-containing molecular glass photoresist compound with high etching resistance, a preparation method therefor, and use thereof are provided. The compound has simple molecular structure, controllable molecular weight, simple synthesis steps, and relatively high thermal stability, resulting in no risk of precipitation in baking and less proneness to deformation in lithography; the negative molecular glass photoresist provided has relatively good film-forming property, relatively high thermal stability, resulting in less proneness to deformation during storage, and low viscosity without the use of additional solvents for dilution. The photoresist prepared by the compound can give a uniform film on a substrate by spin-coating, and the formula can be used in modern lithography technologies such as 365 nm lithography, 248 nm lithography, 193 nm lithography, extreme ultraviolet lithography, electron beam lithography, and the like. By electron beam exposure and development, the exposed pattern has relatively high contrast, excellent resolution, and relatively good sensitivity.

### TECHNICAL FIELD

The present disclosure belongs to the technical field of lithography, and particularly relates to a silicon-containing molecular glass photoresist compound with high etching resistance, a preparation method therefor, and use thereof.

### BACKGROUND

In the late 1950s, scientists invented germanium integrated circuits and silicon integrated circuits. The emergence of integrated circuits has driven the rapid development of semiconductor technology. Modern electronic devices require integrated circuits (chips) with increasingly smaller dimensions and higher integration levels. The minimum feature dimension of integrated circuits has moved from the micron scale and the submicron scale to the nanometer scale.

In 1798, Senefelder invented lithography technology for the first time, which opened the prelude to the development of lithography technology. It was not until around the 1930s that Bell Labs first printed circuits on wafers in this way. Subsequently, the U.S. Army Diamond Ordnance Fuze Laboratory patented and applied the lithography technology for the first time. In 1961, this technology was formally commercialized. With the gradual development of lithography technology, it has gone from ultraviolet lithography (436 nm and 365 nm) to deep ultraviolet lithography (248 nm and 193 nm), and then to electron beam lithography and extreme ultraviolet lithography with smaller dimensions. Current extreme ultraviolet lithography (EUVL) is capable of producing patterns with minimum feature dimensions below 7 nm. In the development of semiconductor devices with faster speeds and smaller dimensions, novel photoresist materials and lithography processes are currently being explored jointly by industrial and academic communities.

Molecular glasses are low-molar-mass materials that do not crystallize on a time scale. Amorphous molecular glass materials can form uniform and transparent films, which have a glass transition process specific to polymers. In addition, the molecular glass materials have high thermal stability and isotropy. Compared with the traditional polymer photoresist with molecular weight distribution, the molecular glass photoresist has the advantages of monodispersity, smaller free volume, and no intermolecular chain entanglement, and the molecular glass photoresist and the photoacid generator have approximately the same molecular size and better compatibility.

An etching process is an essential process for achieving high-resolution patterns, and in the process, an upper photoresist pattern is generally transferred to a lower layer using an oxygen plasma. Therefore, the upper photoresist requires a high oxygen plasma etching resistance. There is a need to develop an ultra-high-resolution molecular glass photoresist with high etching resistance to optimize the lithography performance.

### SUMMARY

The object of the present disclosure is to provide a molecular glass photoresist with high etching resistance and a preparation method therefor.

Another object of the present disclosure is to provide use of the molecular glass photoresist with high etching resistance described above in extreme ultraviolet lithography, deep ultraviolet lithography, ultraviolet lithography, and electron beam lithography.

To ease the technical problem described above, the present disclosure provides a compound represented by formula (I):

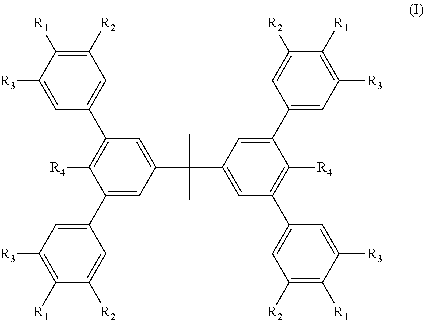

wherein each R₁, R₂, and R₃ is the same or different and is independently selected from H, OH, and the following groups that are unsubstituted or optionally substituted with one, two, or more Rₐ: C₁₋₂₀ alkyl, C₁₋₂₀ alkoxy, C₁₋₂₀ alkoxy-C(═O)O—, C₁₋₂₀ alkoxy-C₁₋₂₀ alkoxy-, C₆₋₂₀ aryl-C(═O)O—C₁₋₂₀ alkoxy-, C₁₋₂₀ alkoxy-C(═O)O—C₁₋₂₀ alkoxy-C₁₋₂₀ alkoxy, C₆₋₂₀ aryl-C(═O)O—C₁₋₂₀ alkoxy-C₁₋₂₀ alkoxy-, C₃₋₂₀ cycloalkyloxy-C(═O)O—, C₃₋₂₀ cycloalkyloxy-C(═O)—C₁₋₂₀ alkoxy-, C₂₋₂₀ alkenyl-C₁₋₂₀ alkoxy-, 3- to 20-membered heterocyclyl-O—, and 3- to 20-membered heterocyclyl-C₁₋₂₀ alkoxy-; and R₁, R₂, and R₃ are not the same group selected from H, OH, or C₁₋₂₀ alkyl at the same time;
each R₄ is the same or different and is independently selected from OH and the following groups that are unsubstituted or optionally substituted with one, two, or more R_{b}: C₁₋₂₀ alkyl, C₁₋₂₀ alkoxy, C₁₋₂₀ alkoxy-C(═O)O—, C₁₋₂₀ alkoxy-C₁₋₂₀ alkoxy-, C₆₋₂₀ aryl-C(═O)O—C₁₋₂₀ alkoxy-, C₁₋₂₀ alkoxy-C(═O)O—C₁₋₂₀ alkoxy-C₁₋₂₀ alkoxy-, C₆₋₂₀ aryl-C(═O)O—C₁₋₂₀ alkoxy-C₁₋₂₀ alkoxy-, C₃₋₂₀ cycloalkyloxy-C(═O)O—, C₃₋₂₀ cycloalkyloxy-C(═O)—C₁₋₂₀ alkoxy-, C₂₋₂₀ alkenyl-C₁₋₂₀ alkoxy-, 3- to 20-membered heterocyclyl-O—, 3- to 20-membered heterocyclyl-C₁₋₂₀ alkoxy-, and —OSi(R_{b1})₃; and at least one of R₄ is —OSi(R_{b1})₃;
each Rₐ and R_{b} is the same or different and is independently selected from oxo(═O), C₁₋₂₀ alkyl, C₁₋₂₀ alkoxy, C₃₋₂₀ cycloalkyl, C₂₋₂₀ alkenyl, 3- to 20-membered heterocyclyl, and C₆₋₂₀ aryl;
each R_{b1} is the same or different and is independently selected from C₁₋₂₀ alkyl, C₃₋₂₀ cycloalkyl, C₂₋₂₀ alkenyl, 3- to 20-membered heterocyclyl, and C₆₋₂₀ aryl.

According to an embodiment of the present disclosure, in R₁, R₂, and R₃, at least one group is not H, or at least one group is not OH, or at least one group is not C₁₋₂₀ alkyl.

According to an embodiment of the present disclosure, each R₁, R₂, and R₃ is the same or different and is independently selected from H, OH, C₁₋₁₀ alkyl, C₁₋₁₀ alkoxy, C₁₋₁₀ alkoxy-C(═O)O—, C₁₋₁₀ alkoxy-C₁₋₁₀ alkoxy-, C₆₋₂₀ aryl-C(═O)O—C₁₋₁₀ alkoxy-, C₁₋₁₀ alkoxy-C(═O)O—C₁₋₁₀ alkoxy-C₁₋₁₀ alkoxy, C₆₋₂₀ aryl-C(═O)O—C₁₋₁₀ alkoxy-C₁₋₁₀ alkoxy-, C₃₋₁₂ cycloalkyloxy-C(═O)O—, C₃₋₁₂ cycloalkyloxy-C(═O)—C₁₋₁₀ alkoxy-, C₂₋₂₀ alkenyl-C₁₋₁₀ alkoxy-, 3- to 12-membered heterocyclyl-O—, and 3- to 12-membered heterocyclyl-C₁₋₁₀ alkoxy-.

According to an embodiment of the present disclosure, each R₁, R₂, and R₃ is the same or different and is independently selected from H, OH, C₁₋₈ alkoxy, C₁₋₈ alkoxy-C(═O)O—, C₁₋₈ alkoxy-C₁₋₈ alkoxy-, C₆₋₁₄ aryl-C(═O)O—C₁₋₈ alkoxy-, C₁₋₈ alkoxy-C(═O)O—C₁₋₈ alkoxy-C₁₋₈ alkoxy, C₆₋₁₄ aryl-C(═O)O—C₁₋₈ alkoxy-C₁₋₈ alkoxy-, C₃₋₈ cycloalkyloxy-C(═O)O—, C₃₋₈ cycloalkyloxy-C(═O)—C₁₋₈ alkoxy-, C₂₋₈ alkenyl-C₁₋₈ alkoxy-, 3- to 8-membered heterocyclyl-O—, and 3- to 8-membered heterocyclyl-C₁₋₈ alkoxy-.

According to an embodiment of the present disclosure, each R₁, R₂, and R₃ is the same or different and is independently selected from H, OH, methoxy,

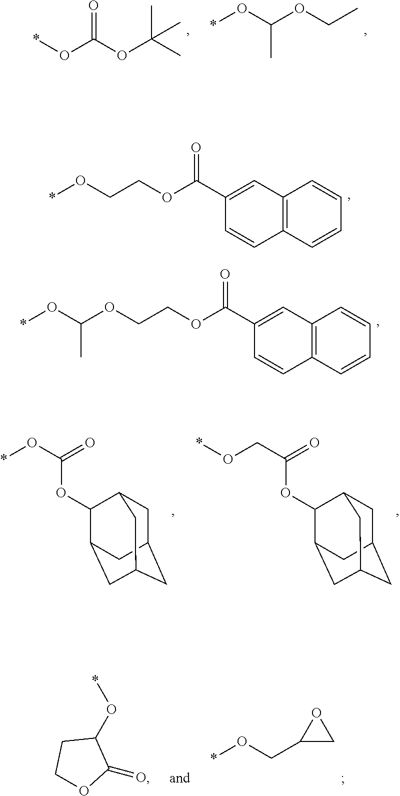

* represents a linking site.

According to an embodiment of the present disclosure, each R₄ is the same or different and is independently selected from OH, C₁₋₂₀ alkyl, C₁₋₂₀ alkoxy, (C₁₋₂₀ alkyl)₃SiO—, (aryl)₂(C₁₋₂₀ alkyl)SiO—, (aryl)(C₁₋₂₀ alkyl)₂SiO—, C₁₋₂₀ alkoxy-C(═O)O—, C₁₋₂₀ alkoxy-C₁₋₂₀ alkoxy, C₆₋₂₀ aryl-C(═O)O—C₁₋₂₀ alkoxy, C₁₋₂₀ alkoxy-C(═O)O—C₁₋₂₀ alkoxy-C₁₋₂₀ alkoxy, C₆₋₂₀ aryl-C(═O)O—C₁₋₂₀ alkoxy-C₁₋₂₀ alkoxy, C₃₋₂₀ cycloalkyloxy-C(═O)O—, C₃₋₂₀ cycloalkyloxy-C(═O)—C₁₋₂₀ alkoxy, C₂₋₂₀ alkenyl-C₁₋₂₀ alkoxy, 3- to 20-membered heterocyclyl-O—, and 3- to 20-membered heterocyclyl-C₁₋₂₀ alkoxy; and at least one of R₄ is (C₁₋₂₀ alkyl)₃SiO—, (aryl)₂(C₁₋₂₀ alkyl)SiO—, and (aryl)(C₁₋₂₀ alkyl)₂SiO—.

According to an embodiment of the present disclosure, each R₄ is the same or different and is independently selected from OH, C₁₋₈ alkoxy, C₁₋₈ alkoxy-C(═O)O—, C₁₋₈ alkoxy-C₁₋₈ alkoxy, C₆₋₁₄ aryl-C(═O)O—C₁₋₈ alkoxy, C₁₋₈ alkoxy-C(═O)O—C₁₋₈ alkoxy-C₁₋₈ alkoxy, C₃₋₈ cycloalkyloxy-C(═O)O—, C₃₋₈ cycloalkyloxy-C(═O)—C₁₋₈ alkoxy, C₂₋₈ alkenyl-C₁₋₈ alkoxy, 3- to 8-membered heterocyclyl-O—, and 3- to 8-membered heterocyclyl-C₁₋₈ alkoxy.

According to an embodiment of the present disclosure, each R₄ is the same or different and is independently selected from OH, methoxy,

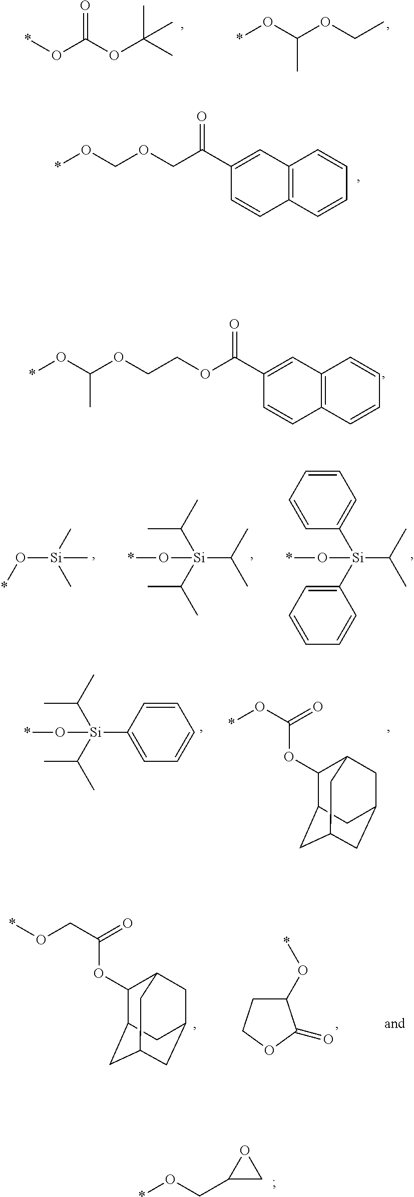

* represents a linking site.

In one embodiment of the present disclosure, in R₁, R₂, R₃, and R₄, the heterocyclyl is oxygen-containing heterocyclyl, for example, 3- to 8-membered oxa-cycloalkyl, such as oxiranyl, oxetanyl, oxolanyl, and oxocyclohexyl.

According to an embodiment of the present disclosure, the compound represented by formula (I) has the following structures:

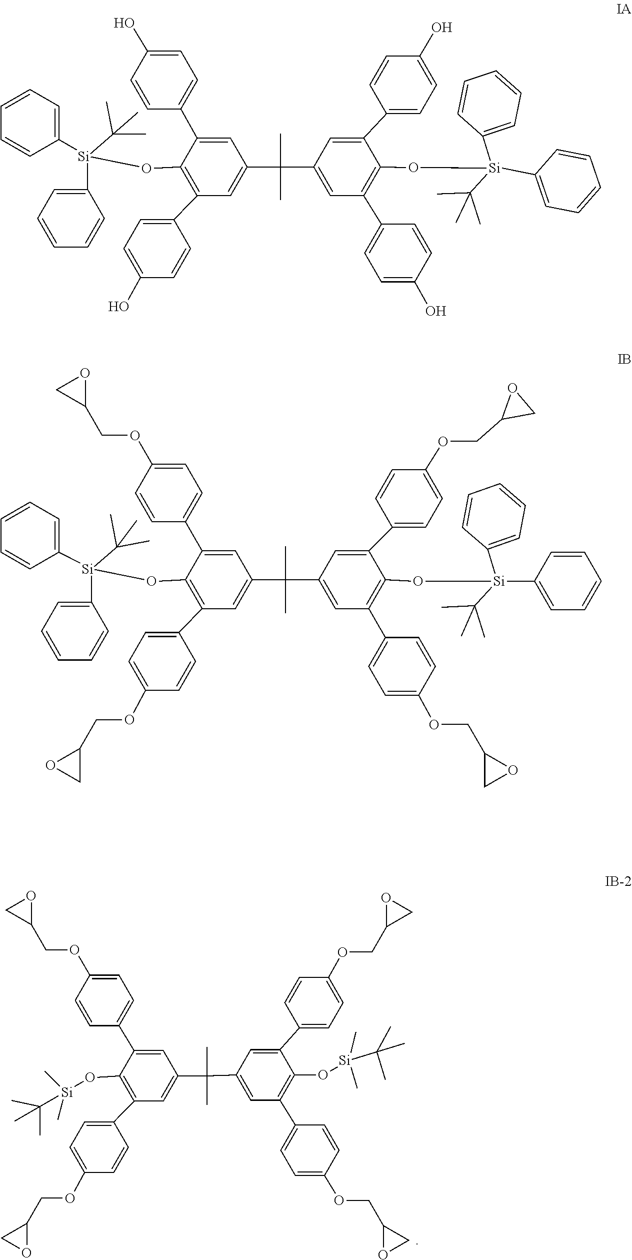 [SMILES: CC(C)(c1cc(-c2ccc(O)cc2)c(O[Si](c2ccccc2)(c2ccccc2)C(C)(C)C)c(-c2ccc(O)cc2)c1)c1cc(-c2ccc(O)cc2)c(O[Si](c2ccccc2)(c2ccccc2)C(C)(C)C)c(-c2ccc(O)cc2)c1 ; CC(C)(c1cc(-c2ccc(OCC3CO3)cc2)c(O[Si](c2ccccc2)(c2ccccc2)C(C)(C)C)c(-c2ccc(OCC3CO3)cc2)c1)c1cc(-c2ccc(OCC3CO3)cc2)c(O[Si](c2ccccc2)(c2ccccc2)C(C)(C)C)c(-c2ccc(OCC3CO3)cc2)c1 ; CC(C)(c1cc(-c2ccc(OCC3CO3)cc2)c(O[Si](C)(C)C(C)(C)C)c(-c2ccc(OCC3CO3)cc2)c1)c1cc(-c2ccc(OCC3CO3)cc2)c(O[Si](C)(C)C(C)(C)C)c(-c2ccc(OCC3CO3)cc2)c1]

The present disclosure further provides a preparation method for the compound represented by formula I, comprising the following steps:

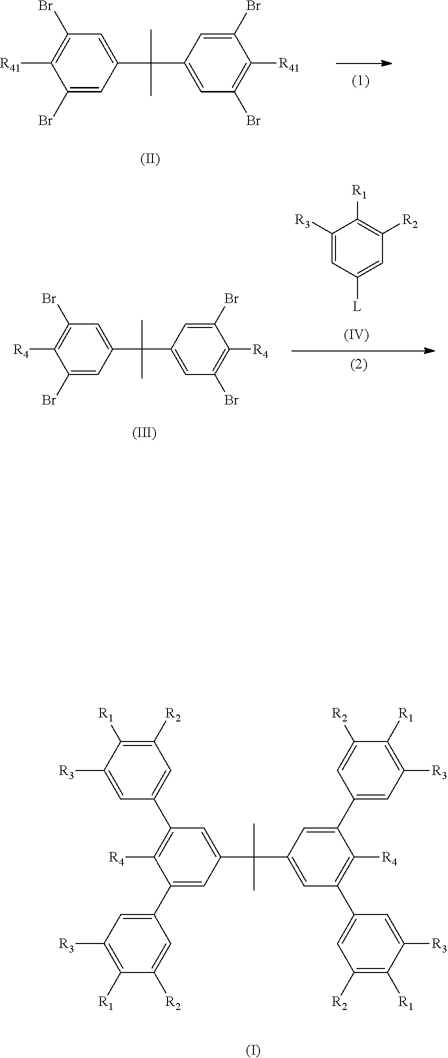

(1) reacting compound (II) with a compound R₄X or (R₄)₂NH to give compound (III); and
(2) reacting the compound (III) with compound (IV) to give the compound represented by formula (I);
wherein R₁, R₂, R₃, and R₄ each independently have the definitions described above; R₄₁ is each independently selected from OH, C₁₋₂₀ alkyl, or C₁₋₂₀ alkoxy, wherein at least one R₄₁ is —OH; X is OH, Cl, Br, or I; L is —B(OH)₂, —B(OC₁₋₂₀ alkyl)₂,

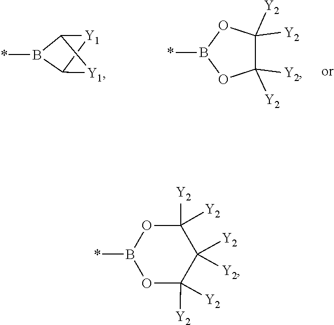

wherein each Y₁ is the same or different and is independently selected from C₁₋₂₀ alkylene, and each Y₂ is the same or different and is independently selected from H or C₁₋₂₀ alkyl; L is preferably —B(OH)₂,

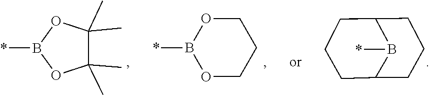

According to an embodiment of the present disclosure, in step (1), when the reactant is R₄X, the reaction is performed under the action of a base, wherein the base is, for example, at least one of imidazole, pyridine, sodium carbonate, potassium carbonate, cesium carbonate, triethylamine, and potassium hydroxide; the temperature of the reaction is, for example, room temperature; a solvent for the reaction is, for example, at least one of tetrahydrofuran, N-methylpyrrolidone, and acetonitrile.

According to an embodiment of the present disclosure, in step (1), when the reactant is (R₄)₂NH, the reaction is performed under the action of an acid, wherein the acid is, for example, concentrated H₂SO₄; the temperature of the reaction is, for example, 80-120° C.

According to an embodiment of the present disclosure, in step (2), the reaction may be performed under the action of a palladium-containing catalyst, wherein the catalyst is, for example, at least one of tetrakis(triphenylphosphine)palladium(0), [1,1′-bis(diphenylphosphino)ferrocene]dichloropalladium(II), tetrakis(triphenylarsine)palladium(0), tetrakis(tri-tert-butylphosphino)palladium(0), tetrakis(trimethoxyphosphine)palladium(0), bis(1,2-bis(diphenylphosphino)ethane)palladium(0), and bis(1,3-bis(diphenylphosphino)propane)palladium (0); the reaction is preferably performed under the action of a base, wherein the base is, for example, at least one of sodium carbonate, cesium carbonate, potassium acetate, potassium phosphate, tetrabutylammonium fluoride, cesium fluoride, or potassium fluoride; a solvent for the reaction is, for example, at least one of acetone, toluene, dioxane, tetrahydrofuran, and anisole; the temperature of the reaction may be 60-150° C., such as 80-120° C.

According to an embodiment of the present disclosure, when R₁, R₂, and R₃ are selected from OH or C₁₋₂₀ alkoxy, R₁, R₂, and R₃ in the compound represented by formula (I) may further participate in the reaction to give a compound represented by formula (I) in which R₁, R₂, and R₃ are other groups except OH or C₁₋₂₀ alkoxy.

According to an embodiment of the present disclosure, the preparation method further comprises the following step (3): when OH is present in R₁, R₂, and R₃ of the compound represented by formula (I), the OH may be further reacted with R₁′X₁, R₂′X₂, and/or R₃′X₃ to give a compound represented by formula (I) in which R₁, R₂, and R₃ are other groups except OH.

According to an embodiment of the present disclosure, the preparation method further comprises the following step (4): when C₁₋₂₀ alkoxy is present in R₁, R₂, and R₃ of the compound represented by formula (I), the C₁₋₂₀ alkoxy may be further reacted to give OH, and the OH may be further subjected to the reaction in step (3) to give a compound represented by formula (I) in which R₁, R₂, and R₃ are other groups except C₁₋₂₀ alkoxy.

Among them, R₁′, R₂′, and R₃′ are groups formed by R₁, R₂, and R₃ losing one oxygen at a linking site to a parent nucleus, respectively, that is, R₁′—O—, R₂′—O—, and R₃′—O— represent R₁, R₂, and R₃, respectively; X₁, X₂, and X₃ are the same or different and are each independently selected from OH, Cl, Br, and I.

According to an embodiment of the present disclosure, in step (3), the reaction is preferably performed in the presence of a catalyst, wherein the catalyst is, for example, at least one of 1,8-diazabicyclo[5.4.0]undec-7-ene (DBU), potassium carbonate, 4-dimethylaminopyridine (DMAP), or sodium hydride; the temperature of the reaction is, for example, room temperature; the reaction is performed, for example, for 2-12 h; the reaction may be performed in the presence of a solvent, wherein the solvent is, for example, at least one of tetrahydrofuran or acetone.

According to an embodiment of the present disclosure, in step (3), when the compound represented by formula (I) and the total amount of R₁′X₁, R₂′X₂, and/or R₃′X₃ as starting materials are in a molar ratio of 1:1 to 1:1.2, a compound represented by formula (I) with a fully protected hydroxyl may be obtained; when the compound represented by formula (I) and R₁′X₁, R₂′X₂, and/or R₃′X₃ as starting materials are in a feeding molar ratio of 1:0.2 to 1:0.8, the compound represented by formula (I) with a partially protected hydroxyl may be obtained.

According to an embodiment of the present disclosure, in step (4), R₁, R₂, and R₃ in the compound represented by formula (I) as a starting material may generate OH under the action of a Lewis acid, wherein the Lewis acid is, for example, at least one of boron tribromide, boron triiodide, boron triiodide-N,N-diethylaniline complex, boron tribromide-dimethyl sulfide, 9-bromo-9-borabicyclo[3.3.0]nonane, and catechol boron bromide (boron trifluoride diethyl etherate catalyzed), and a solvent for the reaction is, for example, dichloromethane or 1,2-dichloroethane.

The present disclosure further provides use of the compound represented by formula (I) in lithography, such as use thereof in a photoresist.

The present disclosure further provides a photoresist composition comprising the compound represented by formula (I).

According to an embodiment of the present disclosure, the photoresist composition may be a positive photoresist composition or a negative photoresist composition.

In one embodiment of the present disclosure, the photoresist composition is a positive photoresist composition a comprising compound (I-a), wherein the compound (I-a) is a compound represented by formula (I) in which at least one group in R₁, R₂, R₃, and R₄ is the following groups that are unsubstituted or optionally substituted with one, two, or more Rₐ: C₁₋₂₀ alkoxy, C₁₋₂₀ alkoxy-C(═O)O—, C₁₋₂₀ alkoxy-C₁₋₂₀ alkoxy, C₆₋₂₀ aryl-C(═O)O—C₁₋₂₀ alkoxy, C₁₋₂₀ alkoxy-C(═O)O—C₁₋₂₀ alkoxy-C₁₋₂₀ alkoxy, C₆₋₂₀ aryl-C(═O)O—C₁₋₂₀ alkoxy-C₁₋₂₀ alkoxy, C₃₋₂₀ cycloalkyloxy-C(═O)O—, C₃₋₂₀ cycloalkyloxy-C(═O)—C₁₋₂₀ alkoxy, C₂₋₂₀ alkenyl-C₁₋₂₀ alkoxy-, 3- to 20-membered heterocyclyl-O—, or 3- to 20-membered heterocyclyl-C₁₋₂₀ alkoxy-, and in which at most one group in R₁, R₂, R₃, and R₄ is OH.

According to an embodiment of the present disclosure, the positive photoresist composition a is composed of the compound (I-a), a photoresist solvent, and a photoacid generator. That is, the positive photoresist composition a is a positive single-molecule photoresist.

Preferably, the positive photoresist composition a comprises 0.1%-10% of the compound (I-a) and 0.01%-1% of the photoacid generator by mass fraction.

According to an embodiment of the present disclosure, the positive photoresist composition a may further optionally comprise an additional photoresist, an acid diffusion inhibitor, and the like.

Preferably, the positive photoresist composition a comprises 0-5% of the additional photoresist and 0-0.1% of the acid diffusion inhibitor by mass fraction.

In one embodiment of the present disclosure, the photoresist composition is a negative photoresist composition b comprising compound (I-b), wherein the compound (I-b) is a compound represented by formula (I) in which R₁, R₂, R₃, and R₄ comprise at least two —OH.

According to an embodiment of the present disclosure, the negative photoresist composition b is composed of the compound (I-b), a photoresist solvent, a photoacid generator, and a cross-linking agent. That is, the negative photoresist composition b is a negative single-molecule photoresist.

Preferably, the negative photoresist composition b comprises 0.1%-10% of the compound (I-b), 0.01%-1% of the photoacid generator, and 0.01%-5% of the cross-linking agent by mass fraction.

According to an embodiment of the present disclosure, the negative photoresist composition b may further optionally comprise an additional photoresist, an acid diffusion inhibitor, and the like.

Preferably, the negative photoresist composition b comprises 0-5% of the additional photoresist and 0-0.1% of the acid diffusion inhibitor.

In one embodiment of the present disclosure, the photoresist composition is a negative photoresist composition c comprising compound (I-c), wherein the compound (I-c) is a compound represented by formula (I) in which at least one group in R₁, R₂, R₃, and R₄ is C₂₋₂₀ alkenyl-C₁₋₂₀ alkoxy, 3- to 8-membered heterocyclyl-O—, or 3- to 8-membered heterocyclyl-C₁₋₈ alkoxy.

According to an embodiment of the present disclosure, the negative photoresist composition c is composed of the compound (I-c), a photoresist solvent, and a photoacid generator. That is, the negative photoresist composition c is another negative single-molecule photoresist.

Preferably, the negative photoresist composition c comprises 0.1%-10% of the compound (I-c) and 0.01%-1% of the photoacid generator by mass fraction.

According to an embodiment of the present disclosure, the negative photoresist composition c may further optionally comprise a photoresist, an acid diffusion inhibitor, a cross-linking agent, and the like.

Preferably, the negative photoresist composition c comprises 0-5% of the photoresist, 0-0.1% of the acid diffusion inhibitor, and 0.01%-5% of the cross-linking agent by mass fraction.

According to an embodiment of the present disclosure, the additional photoresist may be a photoresist known in the art, such as the photoresist disclosed in patent documents 201210156675.6, 201210070713.6, 201611105094.4, 201911329042.9, 201911167289.5, and 202010803879.9.

According to an embodiment of the present disclosure, the photoacid generator may be ionic or non-ionic, for example, selected from at least one of triphenylsulfonium triflate, triphenylsulfonium nonaflate, bis(4-tert-butylphenyl)iodonium p-toluenesulfonate, N-hydroxynaphthalimide triflate, 2-phenyl-(4-phenylthio)phenylsulfonium hexafluoroantimonate, benzyl(4-hydroxyphenyl)methylsulfonium hexafluoroantimonate, a hexafluoroantimonate mixed salt, and the like.

According to an embodiment of the present disclosure, the photoresist solvent may be selected from at least one of propylene glycol methyl ether acetate (PGMEA), ethyl lactate, ethylene glycol monomethyl ether, cyclohexanone, and the like.

According to an embodiment of the present disclosure, the acid diffusion inhibitor may be selected from n-octylamine, tri-n-octylamine, N-methyldi-n-octylamine, tert-octylamine, and the like.

According to an embodiment of the present disclosure, the cross-linking agent may be selected from at least one of tetrakis(methoxymethyl)glycoluril, bisphenol-A-type epoxy propyl ether, and the like.

According to an embodiment of the present disclosure, the photoresist composition may further comprise other additives, such as sensitizers, surfactants, dyes, stabilizers, co-solvents, and the like.

The present disclosure further provides use of the compound represented by formula (I) or the photoresist composition in 365 nm lithography, 248 nm lithography, 193 nm lithography, extreme ultraviolet (EUV) lithography, electron beam lithography (EBL), or other lithography processes.

The present disclosure further provides a photoresist coating, comprising the compound represented by formula (I).

The present disclosure further provides a preparation method for the photoresist coating, comprising coating (such as spin coating) a substrate with the photoresist composition.

Preferably, the coating mode is spin coating the substrate through a spin coater.

Preferably, the substrate may be a silicon wafer, a silicon dioxide wafer, or a compound semiconductor wafer. The silicon wafer is preferably a silicon wafer after a hydrophobic treatment.

### Beneficial Effects

1. The present disclosure introduces a silicon-containing group into a host material molecule of a photoresist to give a photoresist material with high etching resistance.

2. The compound represented by general formula (I) of the present disclosure is a three-dimensional asymmetric and amorphous small molecular compound, features simple molecular structure, controllable molecular weight, and simple synthesis steps, has relatively high thermal stability, resulting in no risk of precipitation in baking and less proneness to deformation in lithography, has relatively high melting point and glass transition temperature (the melting points are all higher than 100° C.), can meet the requirements of lithography technology, and has no change of a film structure in high-temperature baking.

3. The photoresist composition of the present disclosure can be prepared to give a uniform film, wherein the film has good resolution, photosensitivity, and adhesion, and is easy to store, and a molecular glass serving as a matrix component is not precipitated in the film preparation process. The negative photoresist composition prepared by the present disclosure has the advantages of relatively good film-forming property, relatively high thermal stability, resulting in less proneness to deformation during storage, and low viscosity without the use of additional solvents for dilution. After electron beam exposure and development, the exposed pattern has relatively high contrast, excellent resolution, and relatively good sensitivity, and can reach the lithographic line width of 25-30 nm.

### BRIEF DESCRIPTION OF THE DRAWINGS

FIG. 1 is a TGA curve of compound (IB) with a decomposition content of less than 10% at a temperature of 300° C., which can show that compound (1A) has high thermal stability.

FIG. 2 is an SEM result of electron beam exposure of compound (IB) with 60 nm periodic dense lines.

FIG. 3 is an SEM result of electron beam exposure of compound (IB-2) with 60 nm periodic lines.

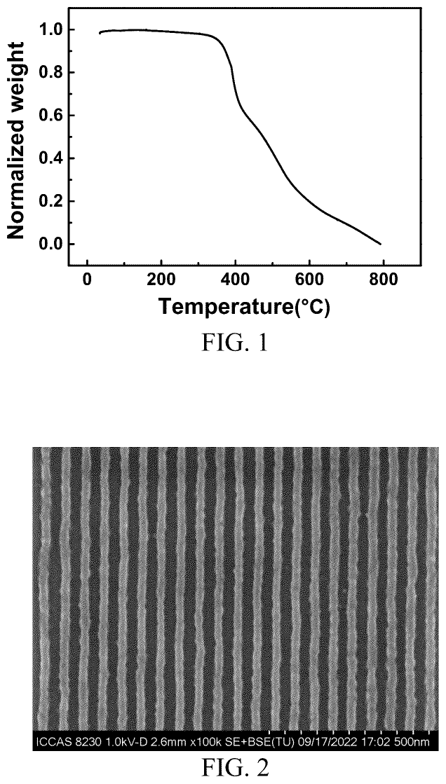

### DEFINITIONS AND DESCRIPTION

Unless otherwise stated, the definitions of groups and terms described in the specification and claims of the present application, including definitions thereof as examples, exemplary definitions, preferred definitions, definitions documented in tables, definitions of specific compounds in the examples, and the like, may be arbitrarily combined and incorporated with each other. The definitions of groups and the structures of the compounds in such combinations and incorporations should be construed as being within the scope of the specification and/or the claims of the present application.

Unless otherwise stated, a numerical range set forth in the description and claims shall be construed as at least including each specific integer value within the range. For example, the numerical range of “1-20” shall be construed as including each integer value in the numerical range “1-20”, i.e., 1, 2, 3, 4, 5, 6, 7, 8, 9, 10, 11, 12, 13, 14, 15, 16, 17, 18, 19, and 20.

The term “C₁₋₂₀ alkyl” should be understood to refer to linear and branched alkyl groups having 1-20 carbon atoms, preferably “C₁₋₈ alkyl”. For example, “C₁₋₈ alkyl” refers to linear and branched alkyl groups having 1, 2, 3, 4, 5, 6, 7, or 8 carbon atoms and “C₁₋₆ alkyl” refers to linear and branched alkyl groups having 1, 2, 3, 4, 5, or 6 carbon atoms. The alkyl is, for example, methyl, ethyl, propyl, butyl, pentyl, hexyl, isopropyl, isobutyl, sec-butyl, tert-butyl, isopentyl, 2-methylbutyl, 1-methylbutyl, 1-ethylpropyl, 1,2-dimethylpropyl, neopentyl, 1,1-dimethylpropyl, 4-methylpentyl, 3-methylpentyl, 2-methylpentyl, 1-methylpentyl, 2-ethylbutyl, 1-ethylbutyl, 3,3-dimethylbutyl, 2,2-dimethylbutyl, 1,1-dimethylbutyl, 2,3-dimethylbutyl, 1,3-dimethylbutyl, 1,2-dimethylbutyl, etc., or isomers thereof.

The term “C₃₋₂₀ cycloalkyl” should be understood to refer to a saturated monovalent monocyclic or bicyclic (e.g., fused, bridged, or spiro) hydrocarbon ring or tricyclic alkane having 3-29 carbon atoms, preferably “C₃₋₁₂ cycloalkyl”, and more preferably “C₃₋₈ cycloalky”. The term “C₃₋₁₂ cycloalkyl” should be understood to refer to a saturated monovalent monocyclic or bicyclic (e.g., bridged or spiro) hydrocarbon ring or tricyclic alkane having 3, 4, 5, 6, 7, 8, 9, 10, 11, or 12 carbon atoms. The C₃₋₁₂ cycloalkyl may be monocyclic hydrocarbyl such as cyclopropyl, cyclobutyl, cyclopentyl, cyclohexyl, cycloheptyl, cyclooctyl, cyclononyl or cyclodecyl, or bicyclic hydrocarbyl such as bornyl, indolyl, hexahydroindolyl, tetrahydronaphthyl, decahydronaphthyl, bicyclo[2.1.1]hexyl, bicyclo[2.2.1]heptyl, bicyclo[2.2.1]heptenyl, 6,6-dimethylbicyclo[3.1.1]heptyl, 2,6,6-trimethylbicyclo[3.1.1]heptyl, bicyclo[2.2.2]octyl, 2,7-diazaspiro[3,5]nonyl, 2,6-diazaspiro[3,4]octyl, or tricyclic hydrocarbyl such as adamantyl.

The term “C₂₋₂₀ alkenyl” should be understood to refer to a linear or branched monovalent hydrocarbyl group containing one or more double bonds and having 2-20 carbon atoms, preferably “C₂₋₁₀ alkenyl”. “C₂₋₁₀ alkenyl” should be understood to preferably refer to a linear or branched monovalent hydrocarbyl group containing one or more double bonds and having 2, 3, 4, 5, 6, 7, 8, 9, or 10 carbon atoms, more preferably “C₂₋₈ alkenyl”. “C₂₋₁₀ alkenyl” should be understood to preferably refer to a linear or branched monovalent hydrocarbyl group containing one or more double bonds and having 2, 3, 4, 5, 6, 7, or 8 carbon atoms, for example, having 2, 3, 4, 5, or 6 carbon atoms (i.e., C₂₋₆ alkenyl) or having 2 or 3 carbon atoms (i.e., C₂₋₃ alkenyl). It should be understood that in the case that the alkenyl comprises more than one double bond, the double bonds can be separated from one another or conjugated. The alkenyl is, for example, vinyl, allyl, (E)-2-methylvinyl, (Z)-2-methylvinyl, (E)-but-2-enyl, (Z)-but-2-enyl, (E)-but-1-enyl, (Z)-but-1-enyl, pent-4-enyl, (E)-pent-3-enyl, (Z)-pent-3-enyl, (E)-pent-2-enyl, (Z)-pent-2-enyl, (E)-pent-1-enyl, (Z)-pent-1-enyl, hex-5-enyl, (E)-hex-4-enyl, (Z)-hex-4-enyl, (E)-hex-3-enyl, (Z)-hex-3-enyl, (E)-hex-2-enyl, (Z)-hex-2-enyl, (E)-hex-1-enyl, (Z)-hex-1-enyl, isopropenyl, 2-methylprop-2-enyl, 1-methylprop-2-enyl, 2-methylprop-1-enyl, (E)-1-methylprop-1-enyl, (Z)-1-methylprop-1-enyl, 3-methylbut-3-enyl, 2-methylbut-3-enyl, 1-methylbut-3-enyl, 3-methylbut-2-enyl, (E)-2-methylbut-2-enyl, (Z)-2-methylbut-2-enyl, (E)-1-methylbut-2-enyl, (Z)-1-methylbut-2-enyl, (E)-3-methylbut-1-enyl, (Z)-3-methylbut-1-enyl, (E)-2-methylbut-1-enyl, (Z)-2-methylbut-1-enyl, (E)-1-methylbut-1-enyl, (Z)-1-methylbut-1-enyl, 1,1-dimethylprop-2-enyl, 1-ethylprop-1-enyl, 1-propylvinyl, or 1-isopropylvinyl.

The term “3- to 20-membered heterocyclyl” refers to a saturated or unsaturated non-aromatic ring or ring system; for example, it is a 4-, 5-, 6-, or 7-membered monocyclic ring system, a 7-, 8-, 9-, 10-, 11-, or 12-membered bicyclic (e.g., fused, bridged, or spiro) ring system, or a 10-, 11-, 12-, 13-, 14-, or 15-membered tricyclic ring system, and contains at least one, e.g., 1, 2, 3, 4, 5, or more heteroatoms selected from O, S, and N, wherein N and S may also be optionally oxidized to various oxidized forms to form nitrogen oxides, —S(O)— or —S(O)₂—. Preferably, the heterocyclyl may be selected from “3- to 10-membered heterocyclyl”. The term “3- to 10-membered heterocyclyl” refers to a saturated or unsaturated non-aromatic ring or ring system and contains at least one heteroatom selected from O, S, and N. The heterocyclyl may be connected to the rest of the molecule through any one of the carbon atoms or the nitrogen atom (if present). The heterocyclyl may include fused or bridged rings as well as spiro rings. In particular, the heterocyclyl may include, but is not limited to: 4-membered rings such as azetidinyl and oxetanyl; 5-membered rings such as tetrahydrofuranyl, dioxolyl, pyrrolidinyl, imidazolidinyl, pyrazolidinyl, and pyrrolinyl; 6-membered rings such as tetrahydropyranyl, piperidyl, morpholinyl, dithianyl, thiomorpholinyl, piperazinyl, and trithianyl; or 7-membered rings such as diazepanyl.

The term “C₆₋₂₀ aryl” should be understood to preferably refer to an aromatic or partially aromatic monovalent monocyclic, bicyclic (e.g., fused, bridged, or spiro) or tricyclic hydrocarbon ring having 6-20 carbon atoms, which may be a single aromatic ring or multiple aromatic rings fused together, preferably “C₆₋₁₄ aryl”. The term “C₆₋₁₄ aryl” should be understood to preferably refer to an aromatic or partially aromatic monovalent monocyclic, bicyclic or tricyclic hydrocarbon ring having 6, 7, 8, 9, 10, 11, 12, 13, or 14 carbon atoms (“C₆₋₁₄ aryl”), in particular a ring having 6 carbon atoms (“C₆ aryl”), e.g., phenyl; biphenyl; a ring having 9 carbon atoms (“C₉ aryl”), e.g., indanyl or indenyl; a ring having 10 carbon atoms (“C₁₀ aryl”), e.g., tetrahydronaphthyl, dihydronaphthyl, or naphthyl; a ring having 13 carbon atoms (“C₁₃ aryl”), e.g., fluorenyl; or a ring having 14 carbon atoms (“C₁₄ aryl”), e.g., anthryl. When the C₆₋₂₀ aryl is substituted, it may be monosubstituted or polysubstituted. In addition, the substitution site is not limited, and may be, for example, ortho-substitution, para-substitution, or meta-substitution.

The term “5- to 20-membered heteroaryl” should be understood to refer to a monovalent monocyclic, bicyclic (e.g., fused, bridged, or spiro) or tricyclic aromatic ring system which has 5-20 ring atoms and contains 1-5 heteroatoms independently selected from N, O, and S, such as “5- to 14-membered heteroaryl”. The term “5- to 14-membered heteroaryl” should be understood to refer to a monovalent monocyclic, bicyclic, or tricyclic aromatic ring system which has 5, 6, 7, 8, 9, 10, 11, 12, 13, or 14 ring atoms, in particular 5, 6, 9, or 10 carbon atoms, contains 1-5, preferably 1-3 heteroatoms independently selected from N, O, and S, and may be benzo-fused in each case. “Heteroaryl” also refers to a group in which a heteroaromatic ring is fused to one or more aryl, alicyclic or heterocyclyl rings, wherein the radical or site of attachment is on the heteroaromatic ring.

### DETAILED DESCRIPTION

The embodiments of the present disclosure will be further illustrated in detail with reference to the following specific examples. It will be appreciated that the following examples are merely exemplary illustrations and explanations of the present disclosure, and should not be construed as limiting the protection scope of the present disclosure. All techniques implemented based on the content of the present disclosure described above are included within the protection scope of the present disclosure. Unless otherwise stated, the starting materials and reagents used in the following examples are all commercially available products or can be prepared using known methods.

### Example 1: Synthesis and Preparation of Compound P1

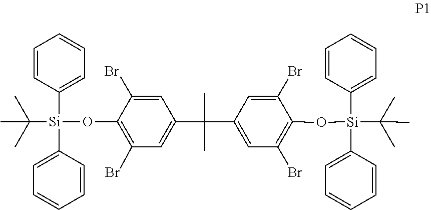 [SMILES: CC(C)(c1cc(Br)c(O[Si](c2ccccc2)(c2ccccc2)C(C)(C)C)c(Br)c1)c1cc(Br)c(O[Si](c2ccccc2)(c2ccccc2)C(C)(C)C)c(Br)c1]

5.44 g (10 mmol) of tetrabromobisphenol A and 1.7 g (25 mmol) of imidazole were added to a 100 mL two-necked flask. The system was purged 3 times. 50 mL of DMF was added to the two-necked flask to dissolve the solids under stirring. 6.9 g (25 mmol) of tert-butyldiphenylchlorosilane (TBDPSCl) was slowly added. The mixture was reacted at room temperature for 3 h. After the reaction was completed, the reaction mixture was diluted with dichloromethane and washed three times with diluted hydrochloric acid and deionized water successively. The mixture was dried over MgSO₄ for 4 h, subjected to solvent exchange with ethanol, and dried under vacuum at 60° C. for 8 h to give compound P1.

### Example 2: Synthesis and Preparation of Compound P2

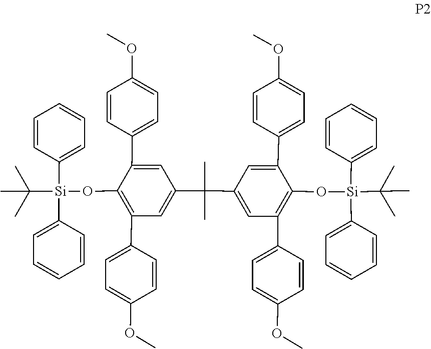 [SMILES: COc1ccc(-c2cc(C(C)(C)c3cc(-c4ccc(OC)cc4)c(O[Si](c4ccccc4)(c4ccccc4)C(C)(C)C)c(-c4ccc(OC)cc4)c3)cc(-c3ccc(OC)cc3)c2O[Si](c2ccccc2)(c2ccccc2)C(C)(C)C)cc1]

10.2 g (10 mmol) of compound P1 and 6.84 g (45 mmol) of 4-methoxyphenylboronic acid were added to a 500 mL three-necked flask successively, 150 mL of 1,4-dioxane was added, and the mixture was fully dissolved under stirring. 80 mL of 40 w.t. % potassium carbonate solution was added under stirring. After the mixture was heated to 90° C., 1.138 g of tetrakis(triphenylphosphine)palladium(0) was added. The mixture was refluxed at 90° C. for 6 h. After the reaction was completed, the reaction mixture was diluted with dichloromethane, washed three times with saturated brine, dried over MgSO₄ for 4 h, precipitated compound P2 with ethanol as a poor solvent, and dried under vacuum at 60° C. for 8 h to give the compound P2.

### Example 3: Synthesis and Preparation of Compound (IA)

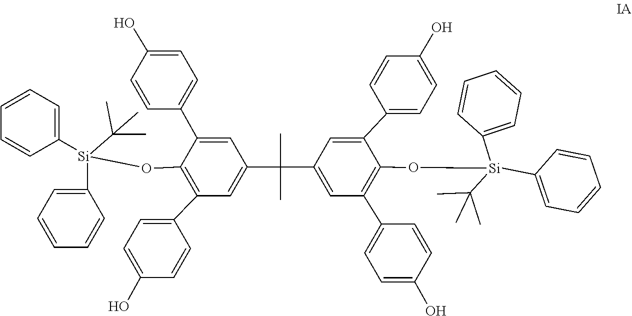 [SMILES: CC(C)(c1cc(-c2ccc(O)cc2)c(O[Si](c2ccccc2)(c2ccccc2)C(C)(C)C)c(-c2ccc(O)cc2)c1)c1cc(-c2ccc(O)cc2)c(O[Si](c2ccccc2)(c2ccccc2)C(C)(C)C)c(-c2ccc(O)cc2)c1]

11.3 g (10 mmol) of compound P2 was dissolved in 100 mL of dichloromethane, and the solution was transferred into a constant pressure dropping funnel. 100 mL of dichloromethane was added to a 500 mL three-necked flask, 4.1 mL (45 mmol) of BBr₃ was added thereto in an ice-water bath, and the mixture was stirred. The reaction temperature was controlled to be 0° C., and the solution in the constant pressure dropping funnel was slowly added to the three-necked flask. After the mixture was reacted for 3 h, the reaction liquid in the three-necked flask was collected into the constant pressure dropping funnel. 200 mL of deionized water was added to a 1000 mL three-necked flask, the reaction temperature was controlled to be 0° C., and the reaction liquid in the constant pressure dropping funnel was added to the three-necked flask to quench the excess BBr₃. After the reaction was completed, the reaction mixture was extracted with ethyl acetate, washed 3 times with deionized water, dried over MgSO₄ for 4 h, precipitated compound (IA) with n-hexane as a poor solvent, and dried under vacuum at 60° C. for 8 h to give the compound (IA). MALDI-TOF (C₇₁H₆₈NaO₆Si₂) m/z: [M+Na]1095.44

### Example 4: Synthesis and Preparation of Compound (IB)

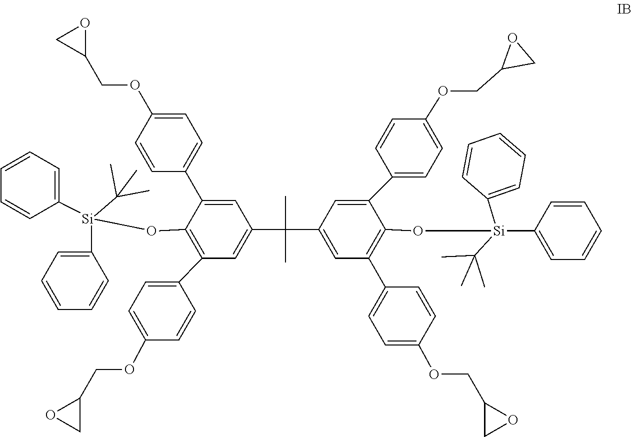 [SMILES: CC(C)(c1cc(-c2ccc(OCC3CO3)cc2)c(O[Si](c2ccccc2)(c2ccccc2)C(C)(C)C)c(-c2ccc(OCC3CO3)cc2)c1)c1cc(-c2ccc(OCC3CO3)cc2)c(O[Si](c2ccccc2)(c2ccccc2)C(C)(C)C)c(-c2ccc(OCC3CO3)cc2)c1]

2.15 g (2 mmol) of compound (IA) and 2.24 g (40 mmol) of KOH were added to a 50 mL two-necked flask successively, followed by the addition of 1.37 g (10 mmol) of 2-(bromomethyl)oxirane and further addition of 10 mL of N-methylpyrrolidone. The mixture was reacted at 65° C. for 4 h. After the reaction was completed, the reaction mixture was diluted with dichloromethane and washed 3 times with deionized water. Anhydrous MgSO₄ was added. The reaction mixture was dried for 4 h, and then separated by a silica gel column (eluent: tetrahydrofuran:petroleum ether=2:1). The product was collected, concentrated by rotary evaporation, and then dried in a vacuum oven at 60° C. for 8 h to give compound (IB) (1.244 g, 48% yield). MALDI-TOF (C₈₃H₈₄NaO₁₀Si₂) m/z: 1319.55. ¹H NMR (300 MHz, DMSO) δ 7.10 (s, 28H), 6.91 (s, 4H), 6.63 (d, J=8.4 Hz, 8H), 4.23 (d, J=11.4 Hz, 5H), 3.73 (dd, J=11.5, 6.3 Hz, 5H), 2.84 (t, J=4.5 Hz, 5H), 2.70 (s, 5H), 1.62 (s, 6H), 0.47 (s, 18H).

### Example 5: The Synthesis Method of Compound (IB-2) was Referred to Those of Examples 1-4

Compound (IB-2) was prepared by changing tert-butyldiphenylsilyl to tert-butyldimethylsilyl, and the molecular formula was as follows: MALDI-TOF (C₈₃H₈₄NaO₁₀Si₂) m/z: 1048.497. ¹H NMR (300 MHz, DMSO) δ 7.42 (d, J=8.5 Hz, 8H), 7.09 (s, 4H), 6.95 (d, J=8.6 Hz, 8H), 4.34 (dd, J=11.4, 2.1 Hz, 4H), 3.82 (dd, J=11.4, 6.6 Hz, 4H), 2.84 (t, J=4.6 Hz, 4H), 2.71 (dd, J=5.0, 2.6 Hz, 4H), 1.74 (s, 6H), 1.35 (s, 4H), 0.66 (s, 18H), −0.78 (s, 12H).

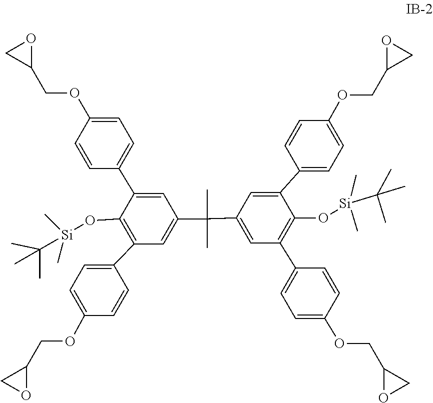 [SMILES: CC(C)(c1cc(-c2ccc(OCC3CO3)cc2)c(O[Si](C)(C)C(C)(C)C)c(-c2ccc(OCC3CO3)cc2)c1)c1cc(-c2ccc(OCC3CO3)cc2)c(O[Si](C)(C)C(C)(C)C)c(-c2ccc(OCC3CO3)cc2)c1]

### Example 6: Preparation of Negative Photoresist Composition Comprising Compound (IB)

100 mg of compound (IB), 7.5 mg of a photoacid generator benzyl(4-hydroxyphenyl)methylsulfonium hexafluoroantimonate, and 7.5 mg of an additive were weighed. 5 mL of a photoresist solvent propylene glycol methyl ether acetate (PGMEA) was weighed, and the concentration of the prepared photoresist solution was 20 mg/mL. After ultrasonic treatment for 30 min, the reaction liquid was filtered three times with a 0.20 m polytetrafluoroethylene film to prepare the negative photoresist composition.

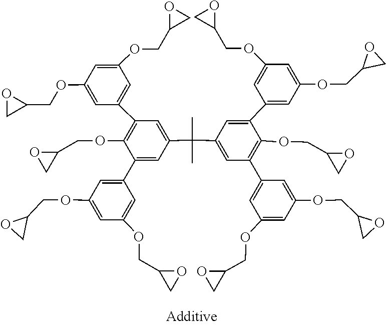 [SMILES: CC(C)(c1cc(-c2cc(OCC3CO3)cc(OCC3CO3)c2)c(OCC2CO2)c(-c2cc(OCC3CO3)cc(OCC3CO3)c2)c1)c1cc(-c2cc(OCC3CO3)cc(OCC3CO3)c2)c(OCC2CO2)c(-c2cc(OCC3CO3)cc(OCC3CO3)c2)c1]

### Example 7: Preparation of Negative Photoresist Composition Comprising Compound (IB-2)

Referring essentially to Example 6, compound (IB-2) was replaced with compound (IB). 30 mg/mL of a negative photoresist composition was prepared.

### Example 8: Lithography Performance of Negative Photoresist Composition Comprising Compound (IB)

An untreated blank silicon wafer was selected, a nitrogen gun was used to blow off the dust on the surface, and the silicon wafer was spin-coated with the negative photoresist composition prepared in Example 6. The spin-coating parameter was set to 2800 rpm/90 s, and the pre-baking parameter was set to 80° C./180 s. The thickness of the film was 43 nm as measured by an optical ellipsometer. An electron beam with an accelerating voltage of 100 kV was adopted for exposure, and the post-baking parameter was 90° C./120 s. Then a developing solution, methyl isobutyl ketone:isopropanol=5:1, was used in the development for 60 s, and the solution was rinsed with isopropanol for 60 s. SEM diagrams were acquired using Hitachi 8230 scanning electron microscope after the development. The specific lithography results are shown in FIG. 2. As can be seen from FIG. 2, the photoresist composition can achieve 30 nm lithography stripes, and has relatively high sensitivity (166 μC/cm²) and high contrast.

### Example 9: Lithography Performance of Negative Photoresist Composition Comprising Compound (IB-2)

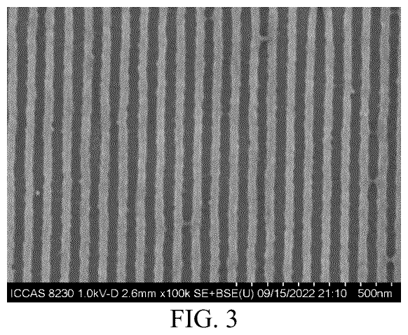

An untreated blank silicon wafer was selected, a nitrogen gun was used to blow off the dust on the surface, and the silicon wafer was spin-coated with the negative photoresist composition prepared in Example 7. The spin-coating parameter was set to 4500 rpm/90 s, and the pre-baking parameter was set to 80° C./180 s. The thickness of the film was 41.2 nm as measured by an optical ellipsometer. An electron beam with an accelerating voltage of 100 kV was adopted for exposure, and the post-baking parameter was 90° C./120 s. Then a developing solution methyl isobutyl ketone was used in the development for 60 s, and the solution was rinsed with isopropanol for 60 s. SEM diagrams were acquired using Hitachi 8230 scanning electron microscope after the development. The specific lithography results are shown in FIG. 3. As can be seen from FIG. 3, the photoresist composition can achieve 30 nm lithography stripes, and has relatively high sensitivity (320 μC/cm²) and relatively high contrast.

The embodiments of the technical solutions of the present disclosure have been described above by way of example. It should be understood that the protection scope of the present disclosure is not limited to the embodiments described above. Any modification, equivalent replacement, improvement, and the like made by those skilled in the art without departing from the spirit and principle of the present disclosure shall fall within the protection scope of the claims of the present application.

1. A compound represented by formula (I): 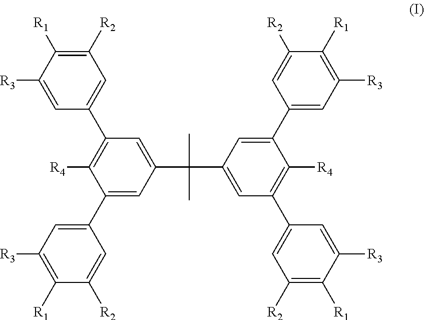
wherein each R₁, R₂, and R₃ is the same or different and is independently selected from H, OH, and the following groups that are unsubstituted or optionally substituted with one, two, or more Rₐ: C₁₋₂₀ alkyl, C₁₋₂₀ alkoxy, C₁₋₂₀ alkoxy-C(═O)O—, C₁₋₂₀ alkoxy-C₁₋₂₀ alkoxy-, C₆₋₂₀ aryl-C(═O)O—C₁₋₂₀ alkoxy-, C₁₋₂₀ alkoxy-C(═O)O—C₁₋₂₀ alkoxy-C₁₋₂₀ alkoxy, C₆₋₂₀ aryl-C(═O)O—C₁₋₂₀ alkoxy-C₁₋₂₀ alkoxy-, C₃₋₂₀ cycloalkyloxy-C(═O)O—, C₃₋₂₀ cycloalkyloxy-C(═O)—C₁₋₂₀ alkoxy-, C₂₋₂₀ alkenyl-C₁₋₂₀ alkoxy-, 3- to 20-membered heterocyclyl-O—, and 3- to 20-membered heterocyclyl-C₁₋₂₀ alkoxy-; and R₁, R₂, and R₃ are not the same group selected from H, OH, or C₁₋₂₀ alkyl at the same time;
each R₄ is the same or different and is independently selected from OH and the following groups that are unsubstituted or optionally substituted with one, two, or more R_{b}: C₁₋₂₀ alkyl, C₁₋₂₀ alkoxy, C₁₋₂₀ alkoxy-C(═O)O—, C₁₋₂₀ alkoxy-C₁₋₂₀ alkoxy-, C₆₋₂₀ aryl-C(═O)O—C₁₋₂₀ alkoxy-, C₁₋₂₀ alkoxy-C(═O)O—C₁₋₂₀ alkoxy-C₁₋₂₀ alkoxy-, C₆₋₂₀ aryl-C(═O)O—C₁₋₂₀ alkoxy-C₁₋₂₀ alkoxy-, C₃₋₂₀ cycloalkyloxy-C(═O)O—, C₃₋₂₀ cycloalkyloxy-C(═O)—C₁₋₂₀ alkoxy-, C₂₋₂₀ alkenyl-C₁₋₂₀ alkoxy-, 3- to 20-membered heterocyclyl-O—, 3- to 20-membered heterocyclyl-C₁₋₂₀ alkoxy-, and —OSi(R_{b1})₃; and at least one of R₄ is —OSi(R_{b1})₃;
each Rₐ and R_{b} is the same or different and is independently selected from oxo(═O), C₁₋₂₀ alkyl, C₁₋₂₀ alkoxy, C₃₋₂₀ cycloalkyl, C₂₋₂₀ alkenyl, 3- to 20-membered heterocyclyl, and C₆₋₂₀ aryl;
each R_{b1} is the same or different and is independently selected from C₁₋₂₀ alkyl, C₃₋₂₀ cycloalkyl, C₂₋₂₀ alkenyl, 3- to 20-membered heterocyclyl, and C₆₋₂₀ aryl.

2. The compound according to claim 1, wherein in R₁, R₂, and R₃, at least one group is not H, or at least one group is not OH, or at least one group is not C₁₋₂₀ alkyl;
preferably, each R₁, R₂, and R₃ is the same or different and is independently selected from H, OH, C₁₋₁₀ alkyl, C₁₋₁₀ alkoxy, C₁₋₁₀ alkoxy-C(═O)O—, C₁₋₁₀ alkoxy-C₁₋₁₀ alkoxy-, C₆₋₂₀ aryl-C(═O)O—C₁₋₁₀ alkoxy-, C₁₋₁₀alkoxy-C(═O)O—C₁₋₁₀ alkoxy-C₁₋₁₀ alkoxy, C₆₋₂₀ aryl-C(═O)O—C₁₋₁₀ alkoxy-C₁₋₁₀ alkoxy-, C₃₋₁₂ cycloalkyloxy-C(═O)O—, C₃₋₁₂ cycloalkyloxy-C(═O)—C₁₋₁₀ alkoxy-, C₂₋₂₀ alkenyl-C₁₋₁₀ alkoxy-, 3- to 12-membered heterocyclyl-O—, and 3- to 12-membered heterocyclyl-C₁₋₁₀ alkoxy-;
preferably, each R₁, R₂, and R₃ is the same or different and is independently selected from H, OH, C₁₋₈ alkoxy, C₁₋₈ alkoxy-C(═O)O—, C₁₋₈ alkoxy-C₁₋₈ alkoxy-, C₆₋₁₄ aryl-C(═O)O—C₁₋₈ alkoxy-, C₁₋₈ alkoxy-C(═O)O—C₁₋₈ alkoxy-C₁₋₈ alkoxy, C₆₋₁₄ aryl-C(═O)O—C₁₋₈ alkoxy-C₁₋₈ alkoxy-, C₃₋₈ cycloalkyloxy-C(═O)O—, C₃₋₈ cycloalkyloxy-C(═O)—C₁₋₈ alkoxy-, C₂₋₈ alkenyl-C₁₋₈ alkoxy-, 3- to 8-membered heterocyclyl-O—, and 3- to 8-membered heterocyclyl-C₁₋₈ alkoxy-;
preferably, each R₁, R₂, and R₃ is the same or different and is independently selected from H, OH, methoxy,

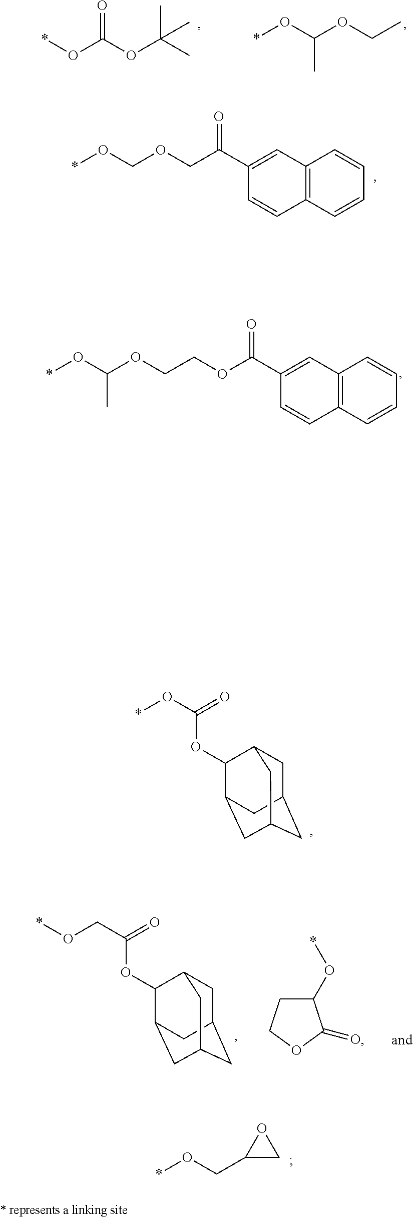

3. The compound according to claim 1, wherein each R₄ is the same or different and is independently selected from OH, C₁₋₂₀ alkyl, C₁₋₂₀ alkoxy, (C₁₋₂₀ alkyl)₃SiO—, (aryl)₂(C₁₋₂₀ alkyl)SiO—, (aryl)(C₁₋₂₀ alkyl)₂SiO—, C₁₋₂₀ alkoxy-C(═O)O—, C₁₋₂₀ alkoxy-C₁₋₂₀ alkoxy, C₆₋₂₀ aryl-C(═O)O—C₁₋₂₀ alkoxy, C₁₋₂₀ alkoxy-C(═O)O—C₁₋₂₀ alkoxy-C₁₋₂₀ alkoxy, C₆₋₂₀ aryl-C(═O)O—C₁₋₂₀ alkoxy-C₁₋₂₀ alkoxy, C₃₋₂₀ cycloalkyloxy-C(═O)O—, C₃₋₂₀ cycloalkyloxy-C(═O)—C₁₋₂₀ alkoxy, C₂₋₂₀ alkenyl-C₁₋₂₀ alkoxy, 3- to 20-membered heterocyclyl-O—, and 3- to 20-membered heterocyclyl-C₁₋₂₀ alkoxy; and at least one of R₄ is (C₁₋₂₀ alkyl)₃SiO—, (aryl)₂(C₁₋₂₀ alkyl)SiO—, and (aryl)(C₁₋₂₀ alkyl)₂SiO—;
preferably, each R₄ is the same or different and is independently selected from OH, C₁₋₈ alkoxy, C₁₋₈ alkoxy-C(═O)O—, C₁₋₈ alkoxy-C₁₋₈ alkoxy, C₆₋₁₄ aryl-C(═O)O—C₁₋₈ alkoxy, C₁₋₈ alkoxy-C(═O)O—C₁₋₈ alkoxy-C₁₋₈ alkoxy, C₃₋₈ cycloalkyloxy-C(═O)O—, C₃₋₈ cycloalkyloxy-C(═O)—C₁₋₈ alkoxy, C₂₋₈ alkenyl-C₁₋₈ alkoxy, 3- to 8-membered heterocyclyl-O—, and 3- to 8-membered heterocyclyl-C₁₋₈ alkoxy;
preferably, each R₄ is the same or different and is independently selected from OH, methoxy, 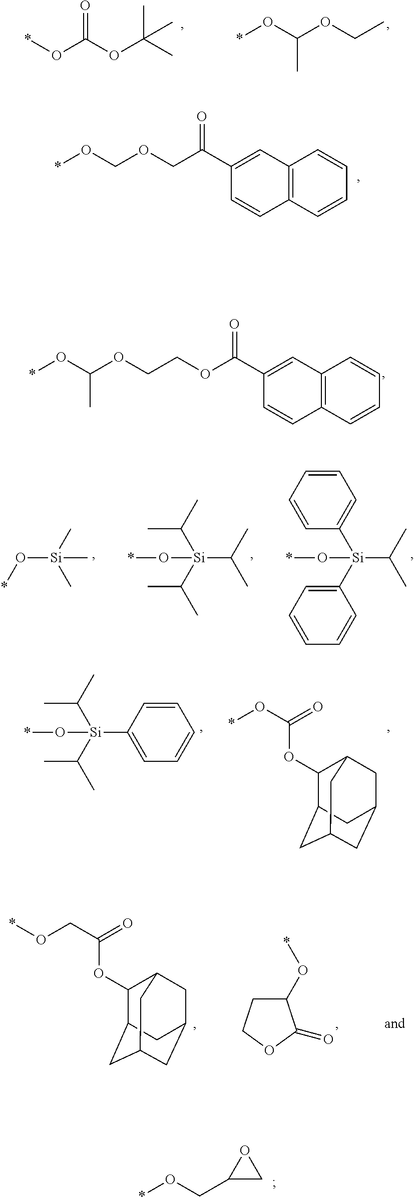
* represents a linking site;
preferably, in R₁, R₂, R₃, and R₄, the heterocyclyl is oxygen-containing heterocyclyl, for example, 3- to 8-membered oxa-cycloalkyl, such as oxiranyl, oxetanyl, oxolanyl, and oxocyclohexyl.

4. The compound according to claim 1, wherein the compound represented by formula (I) has the following structure:

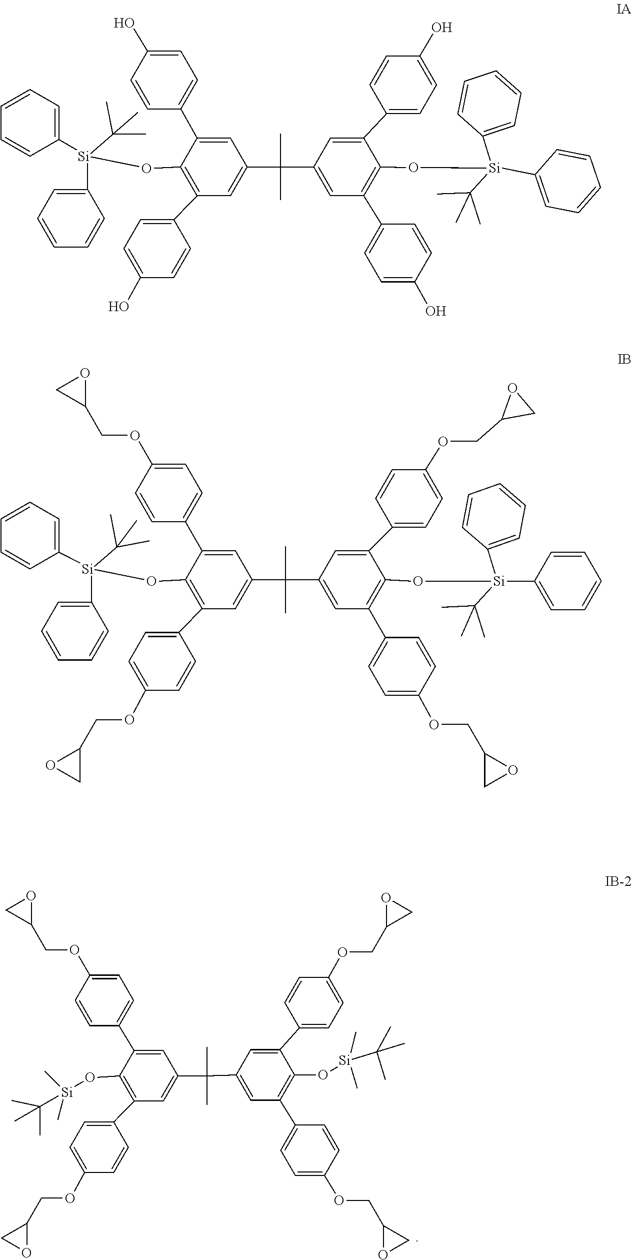 [SMILES: CC(C)(c1cc(-c2ccc(O)cc2)c(O[Si](c2ccccc2)(c2ccccc2)C(C)(C)C)c(-c2ccc(O)cc2)c1)c1cc(-c2ccc(O)cc2)c(O[Si](c2ccccc2)(c2ccccc2)C(C)(C)C)c(-c2ccc(O)cc2)c1 ; CC(C)(c1cc(-c2ccc(OCC3CO3)cc2)c(O[Si](c2ccccc2)(c2ccccc2)C(C)(C)C)c(-c2ccc(OCC3CO3)cc2)c1)c1cc(-c2ccc(OCC3CO3)cc2)c(O[Si](c2ccccc2)(c2ccccc2)C(C)(C)C)c(-c2ccc(OCC3CO3)cc2)c1 ; CC(C)(c1cc(-c2ccc(OCC3CO3)cc2)c(O[Si](C)(C)C(C)(C)C)c(-c2ccc(OCC3CO3)cc2)c1)c1cc(-c2ccc(OCC3CO3)cc2)c(O[Si](C)(C)C(C)(C)C)c(-c2ccc(OCC3CO3)cc2)c1]

5. A preparation method for the compound according to claim 1, comprising the following steps: 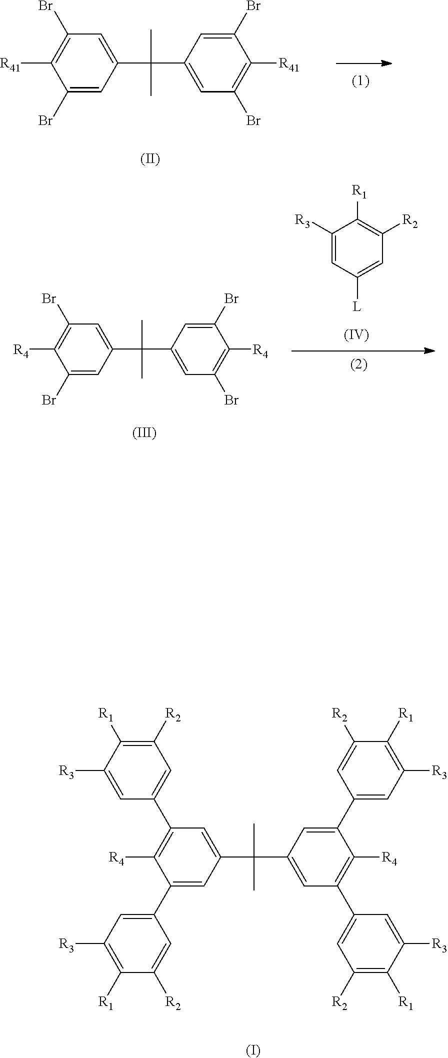
(1) reacting compound (II) with a compound R₄X or (R₄)₂NH to give compound (III); and
(2) reacting the compound (III) with compound (IV) to give the compound represented by formula (I);
wherein R₁, R₂, R₃, and R₄ each independently have the definitions described in claim 1; R₄₁ is each independently selected from OH, C₁₋₂₀ alkyl, or C₁₋₂₀ alkoxy, wherein at least one R₄₁ is —OH; X is OH, Cl, Br, or I; L is —B(OH)₂, —B(OC₁₋₂₀ alkyl)₂, 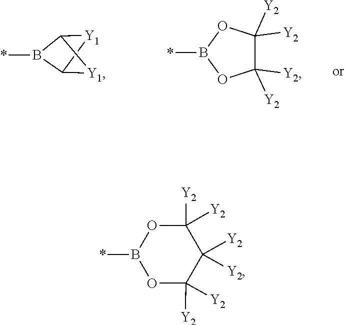
wherein each Y₁ is the same or different and is independently selected from C₁₋₂₀ alkylene, and each Y₂ is the same or different and is independently selected from H or C₁₋₂₀ alkyl; L is preferably —B(OH)₂,

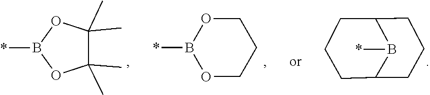

6. Use of the compound according to claim 1 in lithography, such as use thereof in a photoresist.

7. A photoresist composition, comprising the compound according to claim 1;
preferably, the photoresist composition may be a positive photoresist composition or a negative photoresist composition;
preferably, the photoresist composition is selected from a positive photoresist composition a, a negative photoresist composition b, or a negative photoresist composition c described as follows:
positive photoresist composition a:
the positive photoresist composition a comprises compound (I-a), wherein the compound (I-a) is a compound represented by formula (I) according to claim 1 in which at least one group in R₁, R₂, R₃, and R₄ is the following groups that are unsubstituted or optionally substituted with one, two, or more Rₐ: C₁₋₂₀ alkoxy, C₁₋₂₀ alkoxy-C(═O)O—, C₁₋₂₀ alkoxy-C₁₋₂₀ alkoxy, C₆₋₂₀ aryl-C(═O)O—C₁₋₂₀ alkoxy, C₁₋₂₀ alkoxy-C(═O)O—C₁₋₂₀ alkoxy-C₁₋₂₀ alkoxy, C₆₋₂₀ aryl-C(═O)O—C₁₋₂₀ alkoxy-C₁₋₂₀ alkoxy, C₃₋₂₀ cycloalkyloxy-C(═O)O—, C₃₋₂₀ cycloalkyloxy-C(═O)—C₁₋₂₀ alkoxy, C₂₋₂₀ alkenyl-C₁₋₂₀ alkoxy-, 3- to 20-membered heterocyclyl-O—, or 3- to 20-membered heterocyclyl-C₁₋₂₀ alkoxy-, and in which at most one group in R₁, R₂, R₃, and R₄ is OH;
preferably, the positive photoresist composition a is composed of the compound (I-a), a photoresist solvent, and a photoacid generator;
preferably, the positive photoresist composition a comprises 0.1%-10% of the compound (I-a) and 0.01%-1% of the photoacid generator by mass fraction;
negative photoresist composition b:
the negative photoresist composition b comprises compound (I-b), wherein the compound (I-b) is a compound represented by formula (I) according to claim 1 in which R₁, R₂, R₃, and R₄ comprise at least two —OH;
preferably, the negative photoresist composition b is composed of the compound (I-b), a photoresist solvent, a photoacid generator, and a cross-linking agent;
preferably, the negative photoresist composition b comprises 0.1%-10% of the compound (I-b), 0.01%-1% of the photoacid generator, and 0.01%-5% of the cross-linking agent by mass fraction;
negative photoresist composition c:
the negative photoresist composition c comprises compound (I-c), wherein the compound (I-c) is a compound represented by formula (I) according to claim 1 in which at least one group in R₁, R₂, R₃, and R₄ is C₂₋₂₀ alkenyl-C₁₋₂₀ alkoxy, 3- to 8-membered heterocyclyl-O—, or 3- to 8-membered heterocyclyl-C₁₋₈ alkoxy;
preferably, the negative photoresist composition c is composed of the compound (I-c), a photoresist solvent, and a photoacid generator;
preferably, the negative photoresist composition c comprises 0.1%-10% of the compound (I-c) and 0.01%-1% of the photoacid generator by mass fraction.

8. Use of the photoresist composition according to claim 7 in 365 nm lithography, 248 nm lithography, 193 nm lithography, extreme ultraviolet (EUV) lithography, or electron beam lithography (EBL) process.

9. A photoresist coating, comprising the photoresist composition according to claim 7.

10. A preparation method for the photoresist coating according to claim 9, comprising coating a substrate with the photoresist composition.
